(19) United States
(12) Patent Application Publication
(10) Pub. No.: US 2025/0271913 A1
(43) Pub. Date: Aug. 28, 2025

(54) COMPUTER MOTHERBOARD

(71) Applicant: Rouchon Industries, Inc. d/b/a Swiftech, Anaheim, CA (US)

(72) Inventor: Stephen Mounioloux, Anaheim, CA (US)

(73) Assignee: Rouchon Industries, Inc. d/b/a Swiftech, Anaheim, CA (US)

(21) Appl. No.: 18/590,652

(22) Filed: Feb. 28, 2024

(51) Int. Cl. G06F 1/18; H05K 7/14

(52) U.S. Cl. CPC G06F 1/185; G06F 1/186; H05K 7/1408; H05K 7/1429

(57) ABSTRACT

The present disclosure provides for a computing system. The computing device may include a motherboard. The motherboard may include a first edge, a second edge, a third edge opposite the first edge, and a fourth edge opposite the second edge. The first edge may be longer than the second edge. The computing device may further include socket for a central processing unit disposed on the motherboard. The computing device may further include an expansion connector. The expansion connector may include one or more expansion slots oriented parallel relative to the motherboard, and be configured to receive an add-on card such that the add-on card is parallel relative to the motherboard.

### CROSS-REFERENCES TO RELATED APPLICATIONS

Not applicable.

### STATEMENT REGARDING FEDERALLY SPONSORED RESEARCH OR DEVELOPMENT

Not Applicable.

### REFERENCE TO SEQUENCE LISTING OR COMPUTER PROGRAM LISTING APPENDIX

Not Applicable.

### BACKGROUND

The present disclosure relates generally to computing devices. More particularly, the present disclosure relates to motherboards with add-on cards, such as graphics processing units (“GPUs”).

A personal computer is a stand-alone desktop computing device housed in a chassis. Such computing devices typically include a motherboard and central processing unit (“CPU”) positioned thereon, along with other circuitry and electrical components. In many computing devices, an add-on card such as a GPU is connected to the CPU. Conventional computing devices are in alignment with a standard that orients the GPU perpendicular to the motherboard. However, such orientation has been found to present a number of issues. For instance, due to the fact that motherboards are typically oriented parallel to the elongate shape of the chassis, the perpendicular orientation of the GPU relative to the motherboard blocks airflow running through the chassis. Moreover, other components, such as memory modules, are also oriented perpendicular to the motherboard, and thus cut off such airflow that would otherwise reach the GPU itself. As the processing power of computing devices has increased, more heat is generated within computing devices and, thus, more airflow is required in order to cool the GPU (and other components) in order to allow for optimal function of the computing device.

Additionally, the standard by which many conventional computing devices follow requires a power connector to be oriented perpendicular to the motherboard. Such orientation requires the use of various ribbon cables that must navigate one or more contours in order to reach the correct panel of the chassis, and thus connect to an external power source. Such contours often lead to degradation and otherwise suboptimal function.

It would be advantageous to provide a computing device that addresses the increasing severity of these issues, in addition to other problems. What is needed, then, are improvements in apparatuses and methods for computing devices.

### BRIEF SUMMARY

This Brief Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

One aspect of the present disclosure is a computing device. The computing device may include a motherboard. The motherboard may include a first edge, a second edge, a third edge opposite the first edge, and a fourth edge opposite the second edge. The first edge may be longer than the second edge. The computing device may further include a socket disposed on the motherboard and configured to receive a central processing unit. The computing device may further include an expansion connector. The expansion connector may include one or more expansion slots oriented parallel relative to the motherboard. In some embodiments, the expansion connector is a Peripheral Component Interconnect Express connector.

In some embodiments, the computing device further includes an add-on card disposed on the expansion connector, such that the add-on card is oriented parallel relative to the motherboard. In further embodiments, the add-on card is coplanar relative to the motherboard. In some cases, the add-on card is a graphics processing unit.

In some embodiments, the computing device further includes a power connector disposed on the motherboard along the second edge of the motherboard. The power connector may include one or more power connector slots oriented parallel relative to the motherboard.

In some embodiments, the computing device further includes one or more input/output connectors disposed on the motherboard located along the fourth edge of the motherboard. In further embodiments, the computing device further includes a memory module disposed on the motherboard.

In further embodiments, the computing device includes a chassis. The chassis may include a back panel, a sleeve, and a mounting panel. The back panel may be removably secured to the sleeve, and the mounting panel may be disposed on the back panel, such that the mounting panel extends into the sleeve. In such embodiments, the motherboard may be disposed on the mounting panel and oriented parallel to the mounting panel. In some embodiments, the add-on card and the motherboard are oriented vertically. For instance, the add-on card may be located above the motherboard. In this sense, the one or more input/output connectors may be facing the back panel. In some embodiments, the back panel includes an input/output shield aligned with the add-on card.

Another aspect of the present disclosure is a method of providing the aforementioned computing device. The method may include providing the motherboard, installing the central processing unit on the motherboard, and installing the add-on card on the motherboard, such that the add-on card is oriented parallel to the motherboard.

In some embodiments, the method may further include installing an expansion connector on the motherboard, securing the motherboard to the back panel, and securing the back panel to the sleeve, such that the motherboard is inserted within the sleeve, and the chassis is formed by the sleeve and the back panel.

Numerous other objects, advantages and features of the present disclosure will be readily apparent to those of skill in the art upon a review of the following drawings and description of a preferred embodiment.

### BRIEF DESCRIPTION OF THE DRAWINGS

FIG. 1 is a front view of a motherboard of a computing device, according to some embodiments of the present disclosure.

FIG. 2 is side view of the motherboard of FIG. 1, according to some embodiments of the present disclosure.

FIG. 3 is a front view of the motherboard of FIG. 1 with an add-on card connected thereto, according to some embodiments of the present disclosure.

FIG. 4 is a side view of the motherboard of FIG. 3, according to some embodiments of the present disclosure.

FIG. 5 is a front view of an exemplary implementation of a motherboard of a computing device, according to some embodiments of the present disclosure.

FIG. 6 is a front view of an exemplary implementation of a motherboard of a computing device, according to some embodiments of the present disclosure.

FIG. 7 is an upper perspective view of the motherboard of FIG. 6, according to some embodiments of the present disclosure.

FIG. 8 is a lower perspective view of the motherboard of FIG. 6, according to some embodiments of the present disclosure.

FIG. 9 is a rear view of the motherboard of FIG. 6, according to some embodiments of the present disclosure.

FIG. 10 is a front view of the motherboard of FIG. 6 with an add-on card connected thereto, according to some embodiments of the present disclosure.

FIG. 11 is a rear perspective view of the motherboard of FIG. 10 positioned within a chassis, according to some embodiments of the present disclosure.

FIG. 12 is a front perspective view of the motherboard of FIG. 10 positioned within a chassis, according to some embodiments of the present disclosure.

FIG. 13 is a rear view of the motherboard of FIG. 10 positioned within a chassis, according to some embodiments of the present disclosure.

FIG. 14 is a perspective view of the motherboard of FIG. 10 secured to a back panel for a chassis, according to some embodiments of the present disclosure.

FIG. 15 is a front view of the motherboard of FIG. 1 with mounting holes, according to some embodiments of the present disclosure.

FIG. 16 is a schematic view of the motherboard of FIG. 1 with mounting holes, according to some embodiments of the present disclosure.

FIG. 17 is a rear perspective view of the motherboard of FIG. 14 and a sleeve for a chassis, according to some embodiments of the present disclosure.

FIG. 18 is a front view of the motherboard of FIG. 14 and a sleeve for a chassis, according to some embodiments of the present disclosure.

FIG. 19 is a front perspective view of the motherboard of FIG. 14 and a sleeve for a chassis, according to some embodiments of the present disclosure.

FIG. 20 is a rear perspective view of the motherboard of FIG. 14 and a sleeve for a chassis, according to some embodiments of the present disclosure.

FIG. 21 is a perspective view of a motherboard for a computing device with a power connector, according to some embodiments of the present disclosure.

FIG. 22 is a perspective view of a motherboard for a computing device with a power connector, according to alternative embodiments of the present disclosure.

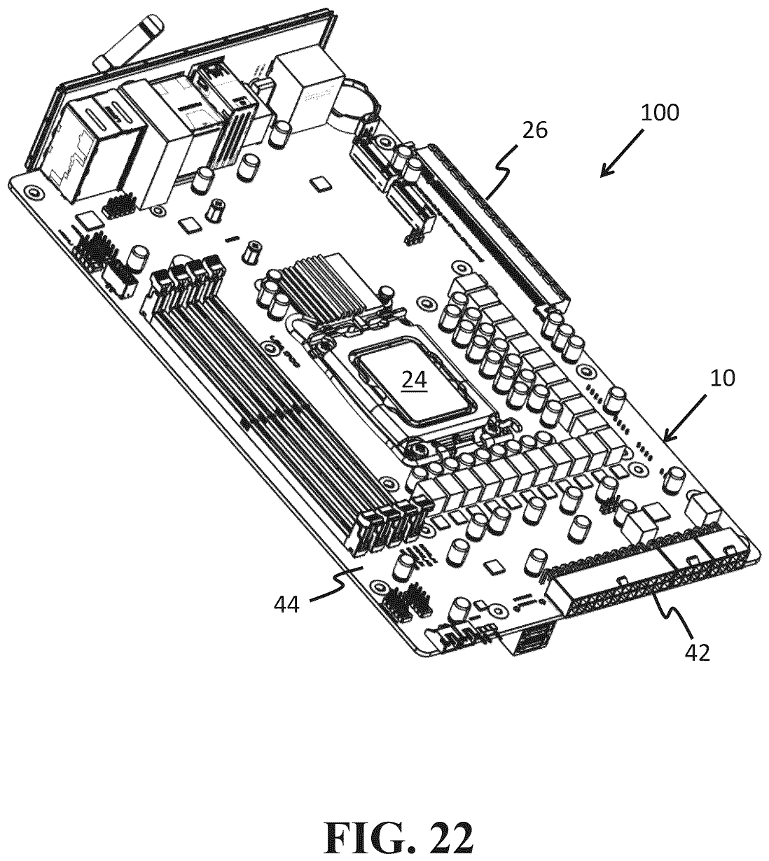

### DETAILED DESCRIPTION

While the making and using of various embodiments of the present invention are discussed in detail below, it should be appreciated that the present invention provides many applicable inventive concepts that are embodied in a wide variety of specific contexts. The specific embodiments discussed herein are merely illustrative of specific ways to make and use the invention and do not delimit the scope of the invention. Those of ordinary skill in the art will recognize numerous equivalents to the specific apparatus and methods described herein. Such equivalents are considered to be within the scope of this invention and are covered by the claims.

In the drawings, not all reference numbers are included in each drawing, for the sake of clarity. In addition, positional terms such as “upper,” “lower,” “side,” “top,” “bottom,” etc. refer to the apparatus when in the orientation shown in the drawing, or as otherwise described. A person of skill in the art will recognize that the apparatus can assume different orientations when in use.

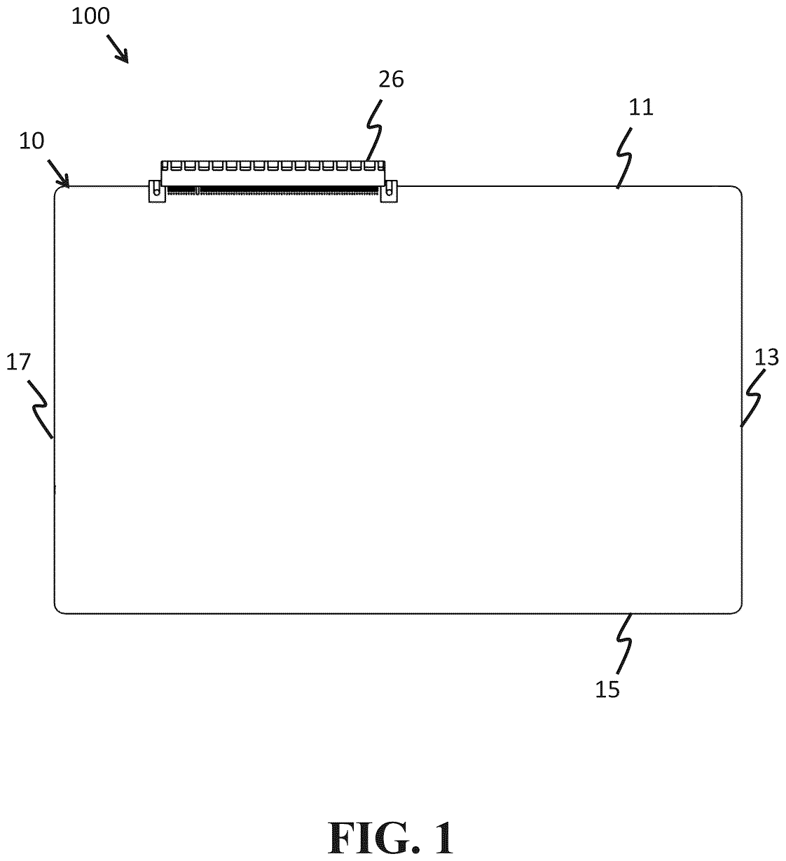

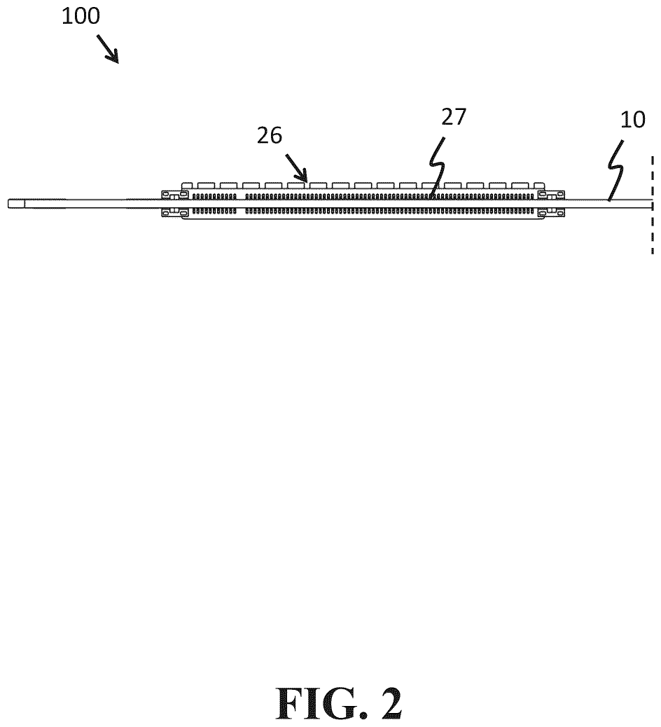

Referring now to FIGS. 1-2, a computing device (“device”) 100 is shown, according to some embodiments of the present disclosure. The device 100 may include a motherboard 10 (e.g., a printed circuit board). The motherboard 10 may include a first edge 11 and a second edge 13. As between the first and second edges 11, 13, the first edge 11 may be of a long, straight dimension, and the second edge 13 may be of a short, straight dimension. In other words, the first edge 11 may be longer than the second edge 13. The motherboard 10 may include a third edge 15 opposite the first edge 11, and a fourth edge 17 opposite the second edge 13. The third edge 15 may be of equal (or substantially equal) length relative to the first edge 11; and the fourth edge 17 may be of equal (or substantially equal) length relative to the second edge 13.

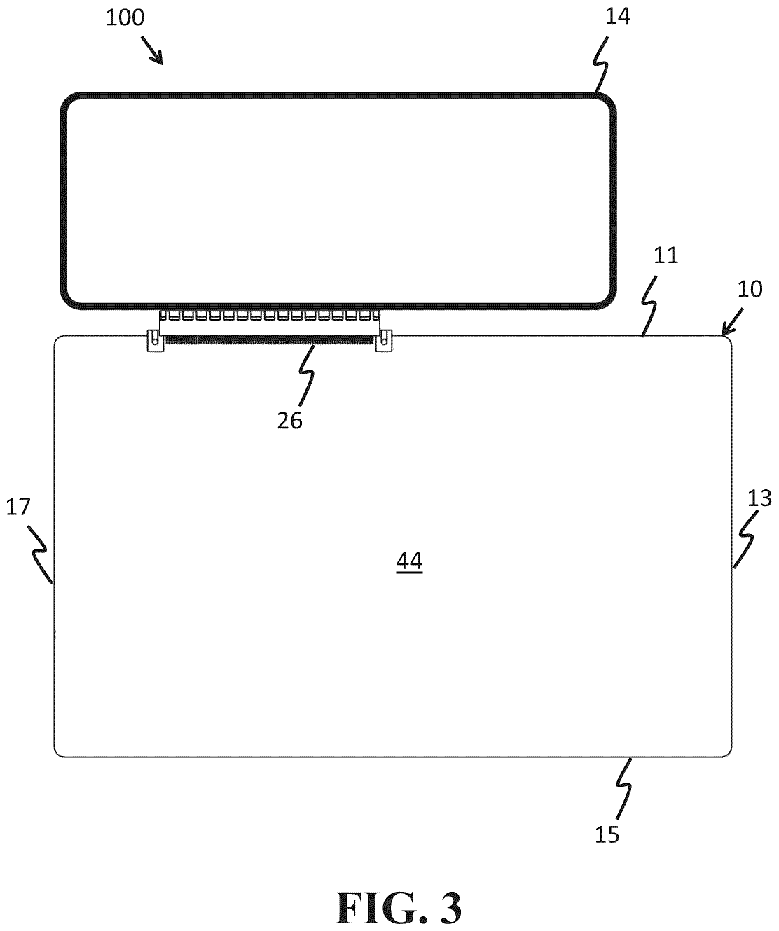

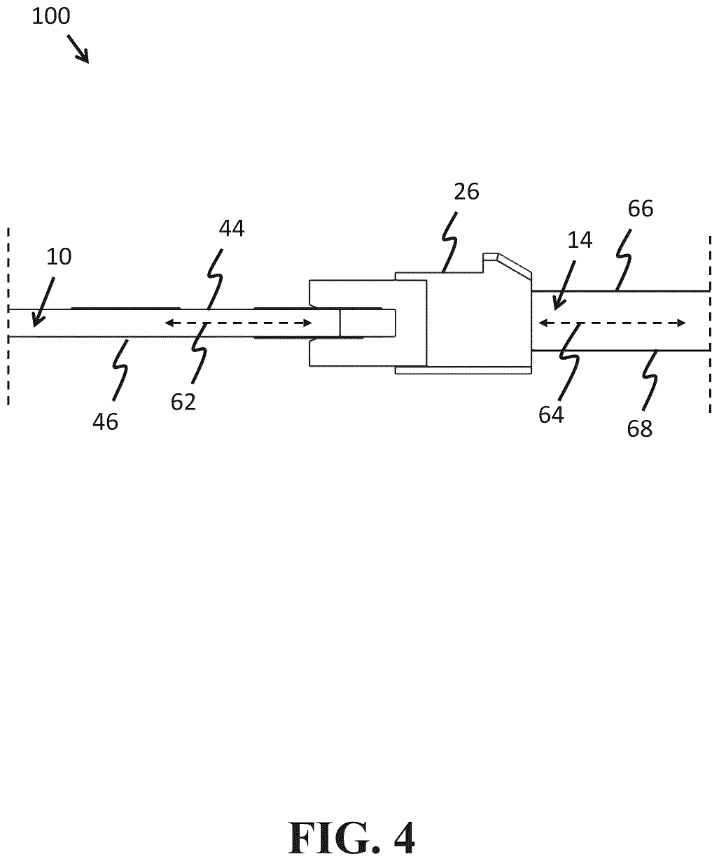

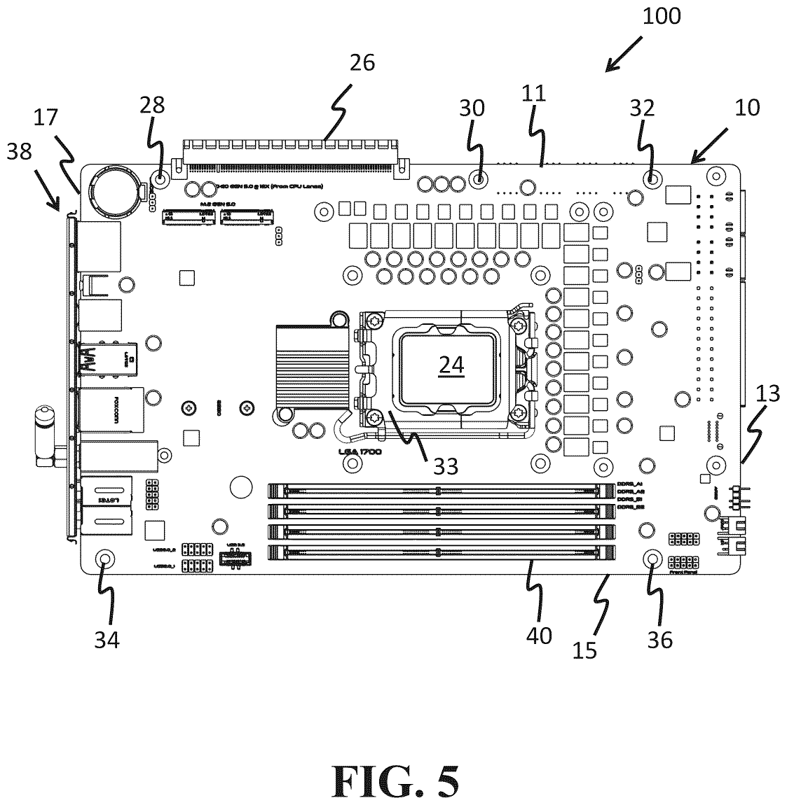

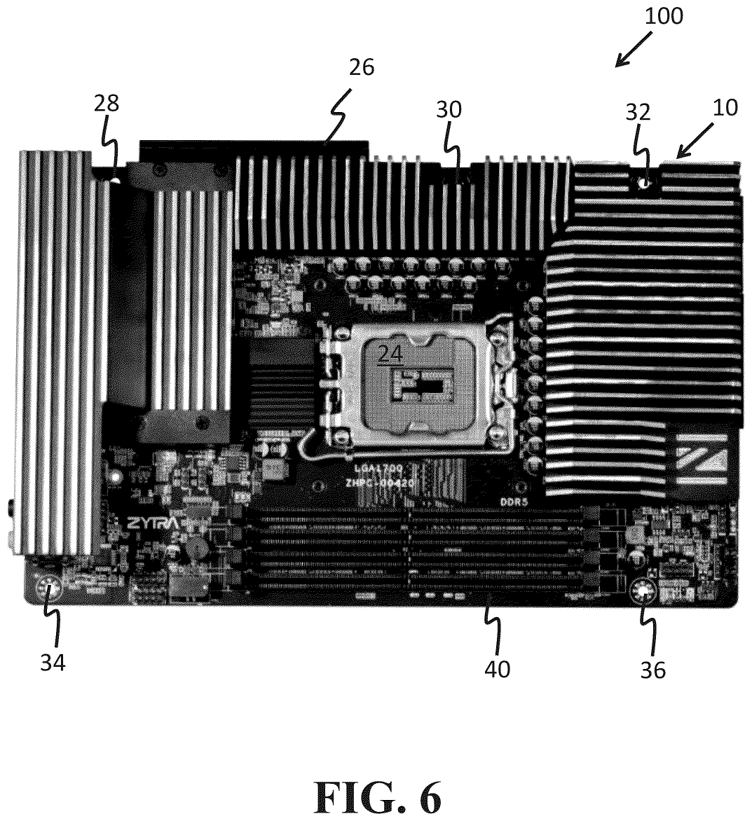

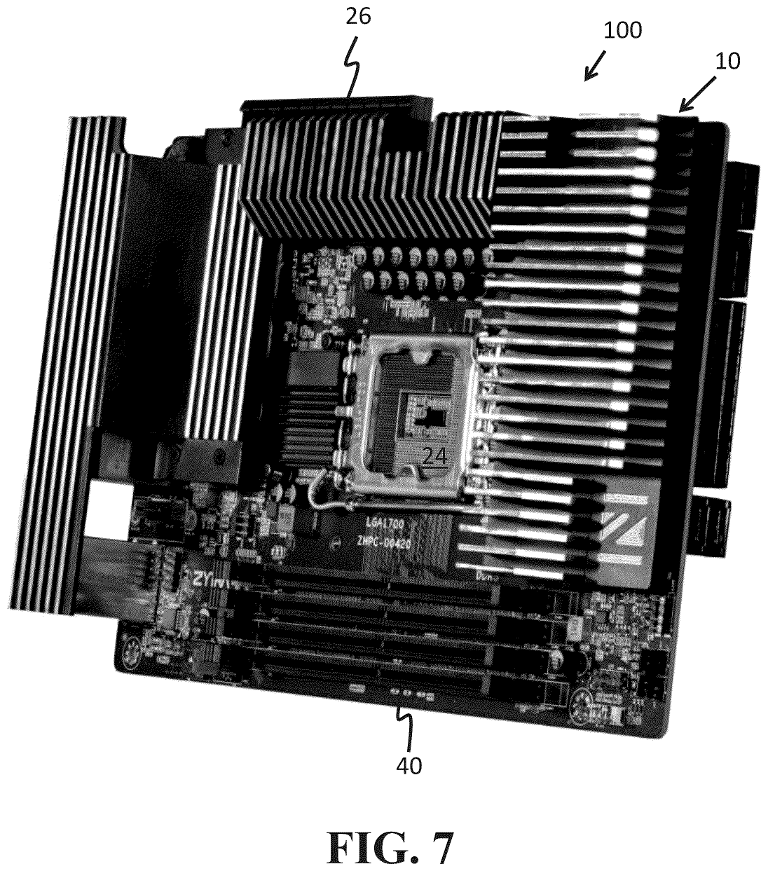

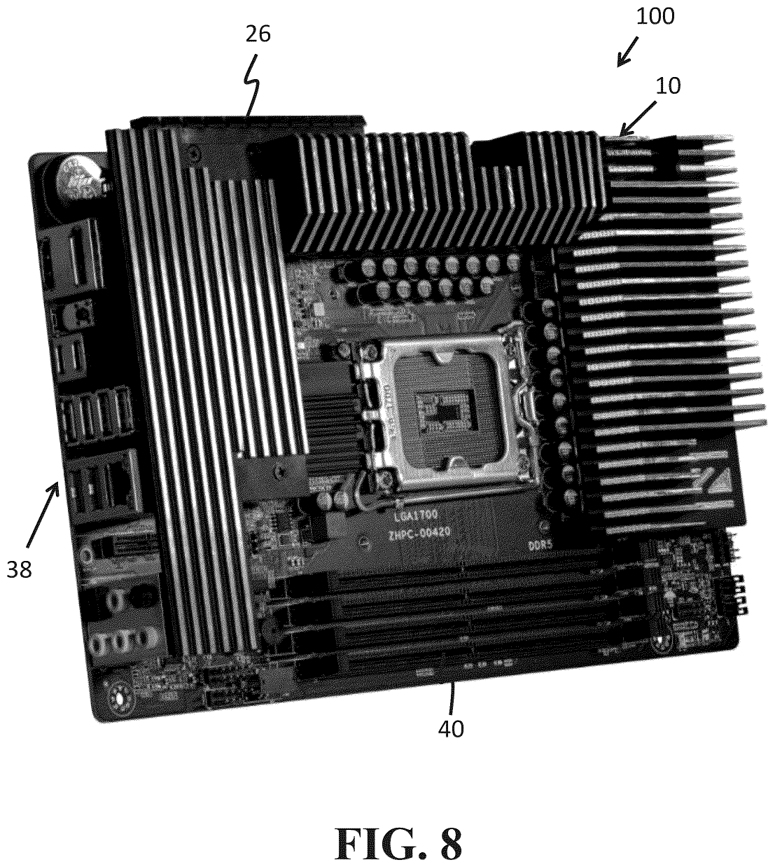

As discussed in greater detail below with reference to FIGS. 5-9, the device 100 may include a socket 33 disposed on the motherboard. The socket 33 may be configured to receive a central processing unit (“CPU”) 24. It should be appreciated that other such sockets and components received thereon may be disposed on the motherboard 10, amounting to suitable control circuitry and other electronics. Additionally, as discussed in greater detail below with reference to FIGS. 3-4, The device 100 may include an add-on card 14. Generally, the add-on card 14 (e.g., an expansion board, an expansion card, etc.) may be a hardware component that can be connected to the components of the motherboard 10 in order to enhance the functionality of the device 100. For example, the add-on card 14 may be a graphics processing unit. Of course, the add-on card 14 may be any suitable hardware for being received by an expansion connector 26, as discussed in greater detail below.

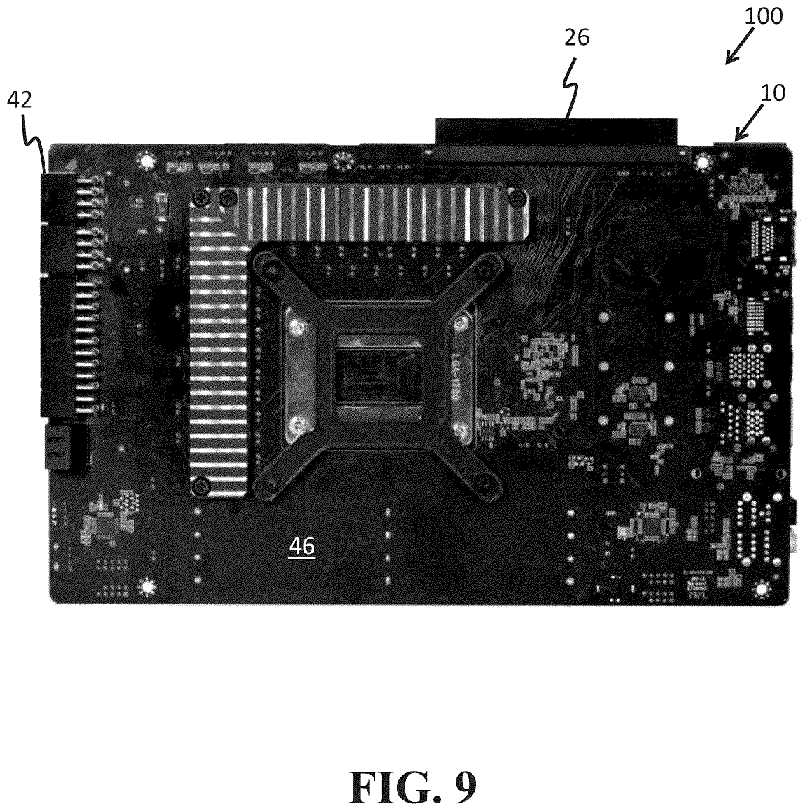

As shown with reference to FIGS. 3, and 9, the motherboard 10 may form a substantially planar body that includes a first face 44 (e.g., a top face on which a substantial amount of such electronics are disposed), and a second face 46 (e.g., a bottom face) opposite and parallel to the first face 44. As shown with reference to FIG. 4, the add-on card 14 may form a substantially planar body that includes a first face 66 and a second face 68 opposite and parallel to the first face 66.

As mentioned above, the device 100 may include the expansion connector 26, which may include one or more expansion connector slots 27 configured to interface with a component of the computing device 100. Depending on the implementation, the expansion connector 26 may be disposed on the motherboard 10 along the first edge 11. For instance, the expansion connector 26 may be positioned on the first edge 11 such that the expansion connector slots 27 face outwards and away from the motherboard 10 (from a top-view perspective as suggested with reference to FIG. 1). Of course, the expansion connector slot(s) 27 may be configured in a generally elongate fashion. Thus, when the expansion connector 26 is disposed on the motherboard 26 as shown with particular reference to FIG. 2, the expansion connector slot(s) 27 may be oriented parallel relative to the motherboard 10 (e.g., parallel relative to the plane generally defined by the planar body of the motherboard 10).

The add-on card 14 may be disposed on the expansion connector 26. Thus, the expansion connector 26 may provide an input/output pathway or route that allows the add-on card 14 to connect to the CPU 24 (and other appropriate components on the motherboard 10) via printed circuit wiring on the motherboard 10. Due to the aforementioned orientation of the expansion connector 26, the add-on card 14, when disposed on the expansion connector 26 as shown, may be oriented parallel relative to the motherboard 10.

In some embodiments, the expansion connector 26 is a peripheral component interconnect (“PCI”). In other embodiments, the expansion connector 26 is a PCI extended (“PCI-X”), which is designed to enhance the legacy PCI for higher bandwidth. In other embodiments still, the expansion connector 26 is a PCI Express (“PCI-e”), which is a high-speed serial computer expansion bus standard designed to replace the legacy PCI and PCI-X. In general, the expansion connector 26 may be a motherboard interface for computer graphics cards, sound cards, hard disk drive host adapters, SSDs, Wi-Fi, and Ethernet hardware connections, and may be configured in any suitable fashion for receiving the add-on card 14 and orienting the add-on card 14 in a parallel configuration relative to the motherboard 10.

Referring now to FIGS. 3-4, the device 100 is shown with the add-on card 14 disposed on the expansion connector 26, according to some embodiments of the present disclosure. As mentioned above, the expansion connector 26 is disposed on (and is oriented parallel to) the first edge 11. In this sense, the expansion connector slots 27 may be oriented perpendicularly (or substantially so) relative to the first edge 11. Thus, the add-on card 14 (or, more generally, the planar feature broadly defined by the shape of the add-on card 14) may be oriented in parallel relative to the motherboard 10 (or, more generally, the planar feature broadly defined by the shape of the motherboard 10). As a first example, the first and/or second faces 44, 46 of the motherboard 10 may be parallel to the first and/or second faces 66, 68 of the add-on card 14. As a second example, a motherboard axis 62 (e.g., an axis that runs parallel to the first and/or second faces 44, 46 of the motherboard 10) may be parallel to a GPU axis 64 (e.g., an axis that runs parallel to the first and/or second faces 66, 68 of the add-on card 14. In further embodiments, the add-on card 14 is coplanar with the motherboard 10.

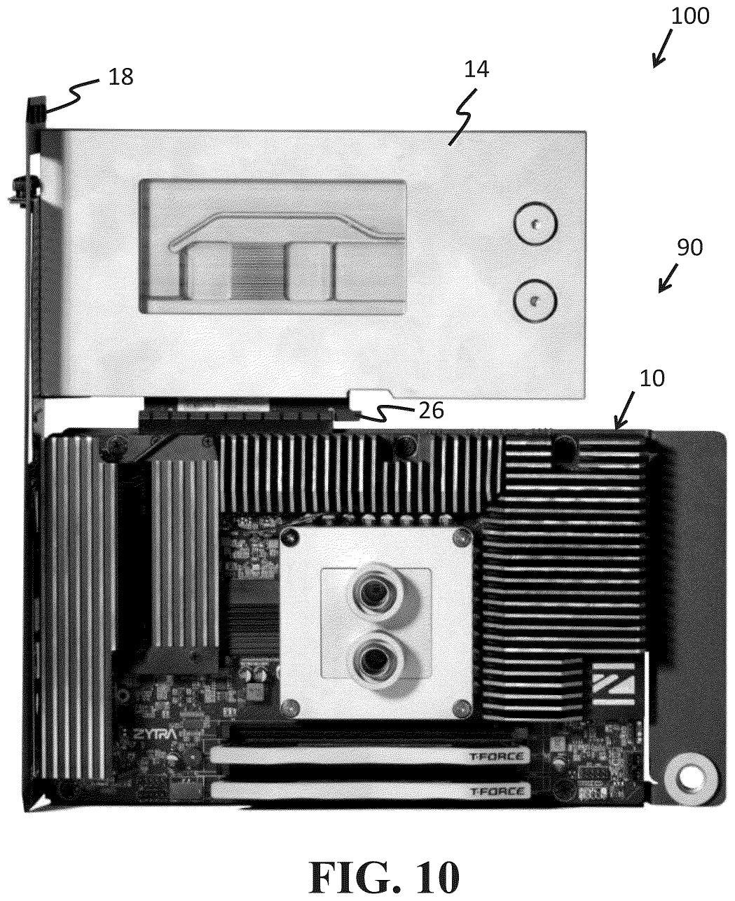

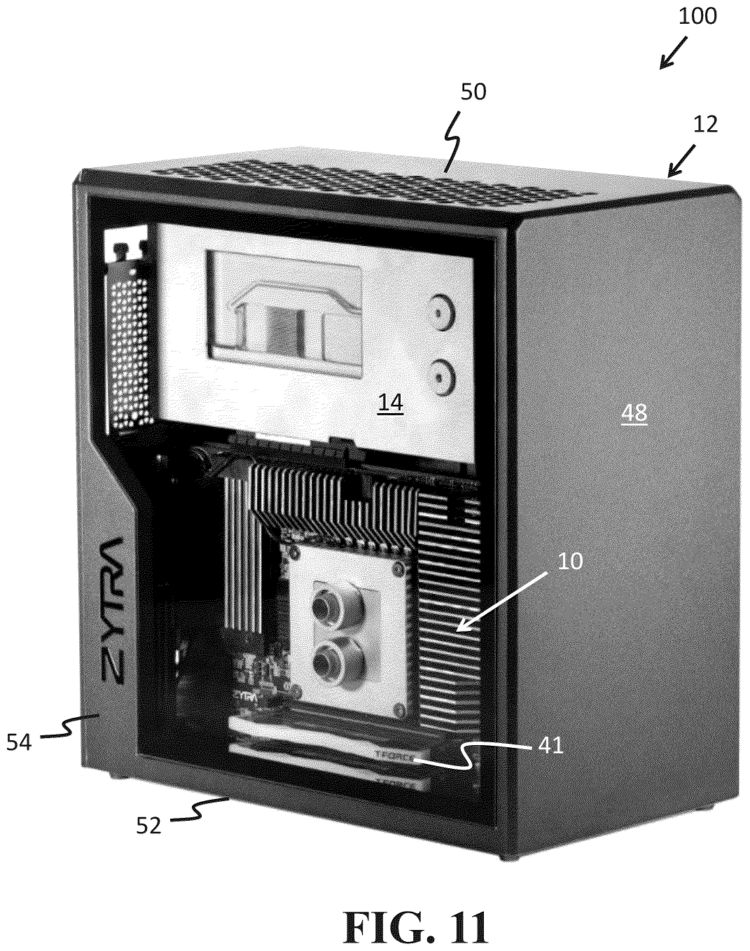

Referring now to FIGS. 5-9, the device 100 is shown, according to some embodiments of the present disclosure. As mentioned above, the device 100 may include the CPU 24 disposed on the motherboard 10, along with control circuitry and other electronics. As a first example, device 100 may include a memory module connector 40 disposed on the motherboard 10. For instance, the memory module 40 may be a random access memory (“RAM”) slot 40. In this sense, and as depicted with reference to FIG. 11, the device 100 may include a memory card 41 disposed on the memory module 40. As a second example, the device 100 may include input/output (“IO”) connectors 38, which may facilitate the connections of IO devices such as a video monitor, mouse, or printer to the control circuitry and other electronics of the device 100. In general, and as depicted with particular reference to FIG. 5 and with additional reference to FIG. 10, the motherboard 10 and one or more of the aforementioned components disposed thereon or connected thereto, including the add-on card 14, may form a motherboard assembly 90.

Referring now to FIG. 10, the device 100 is shown with the motherboard assembly 90 secured to a chassis 12 (or a portion of thereof, as discussed in greater detail below), according to some embodiments of the present disclosure. As shown, the add-on card 14 and the motherboard 10 may be oriented vertically. Thus, the add-on card 14 may be located above the motherboard 10. Of course, in further embodiments, the orientation may be adjusted such that the add-on card 14 is located below the motherboard 10. Moreover, it should be appreciated that the computing system 100 may be oriented in any number of suitable fashions, such that the add-on card 14 is located to the left or right of the motherboard 10. Indeed, it should be noted that the descriptions and depictions discussed herein are exemplary in nature, and should be considered non-limiting embodiments of the present disclosure.

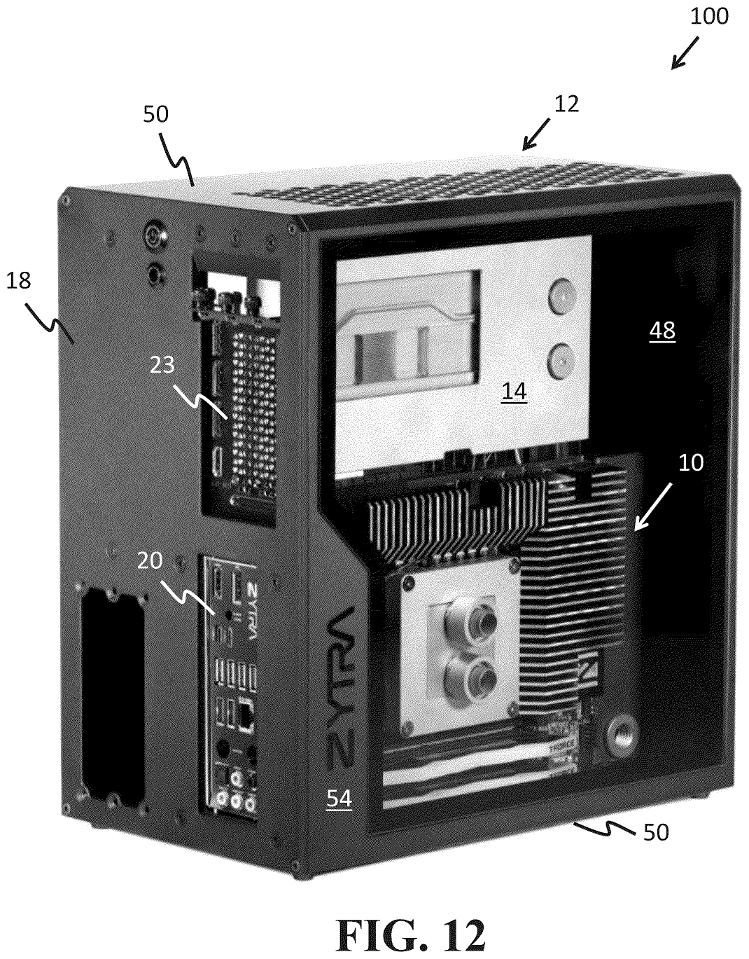

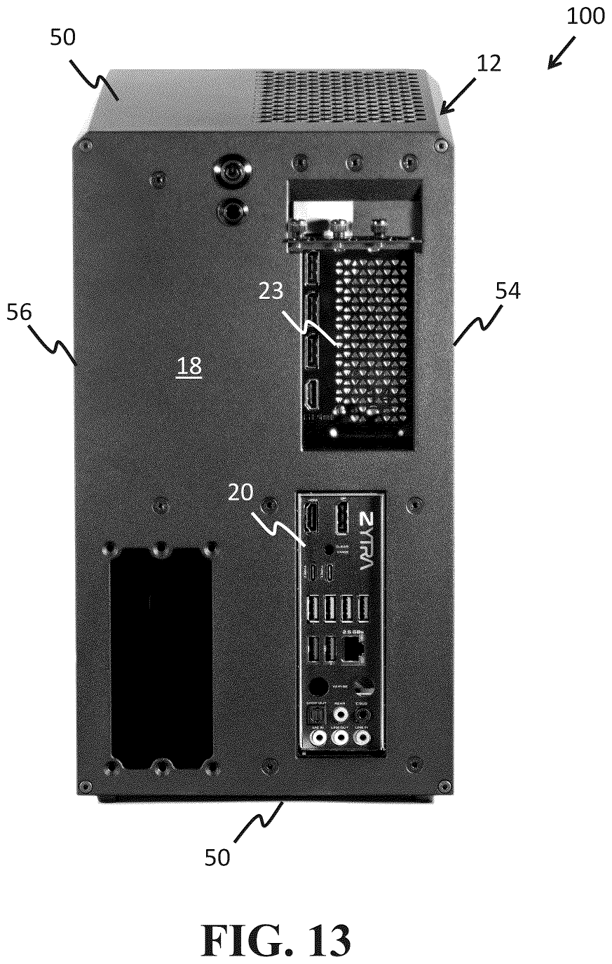

As discussed in greater detail below with reference to FIGS. 11-13, the device 100 may include the chassis 12 configured to house and secure the motherboard assembly 90. The chassis 12 may include a back panel 18. The motherboard 10 and/or the add-on card 14 may be mounted on or otherwise secured to the back panel 18. As shown, the motherboard 10 and/or the add-on card 14 may be oriented perpendicular to the back panel 18.

In some embodiments, the back panel 18 includes an interface 20 configured to secure the one or more IO connectors 38 disposed on the motherboard 10. Additionally, the back panel 18 may include an IO shield 23. The IO shield 23 may be aligned with the add-on card 14. The IO shield 23 may be configured to secure additional IO connectors disposed on the add-on card 14. In some embodiments, particularly in cases where the add-on card 14 is a GPU, the IO shield 23 may include a vent. While the position of the IO shield 23 may be moved to any suitable location(s) on the chassis 12, it should be appreciated that the parallel position of the add-on card 14 relative to the motherboard 10 may advantageously allow a free stream of air to pass through the chassis 12, thus enhancing the cooling effects resulting from air travel throughout the chassis. Moreover, the chassis 12 may be reduced in terms of footprint size due to the vertically structured arrangement of the motherboard assembly 90.

Referring now to FIGS. 11-13, the device 100 is shown with the motherboard assembly 90 housed within the chassis 12, according to some embodiments of the present disclosure. In addition to the back panel 18 (e.g., a back panel), the chassis 12 may further include sleeve 19. The sleeve 19 may be formed as an open box by a front panel 48, a top panel 50, a bottom panel 52, a right panel 54, and a left panel 56. The back panel 18 may be removably secured to (e.g., over the open portion of) the sleeve 19. When the back panel 18 is secured to the sleeve 19 as shown, the chassis 12 may form a box as suggested above. Owing to the aforementioned box shape, the back and front panels 18, 48 may be parallel (or substantially parallel), the top and bottom panels 50, 52 may be parallel (or substantially parallel), and the left and right panels 54, 56 may be parallel (or substantially parallel). Thus, the chassis 12 may form a box around the motherboard assembly 90.

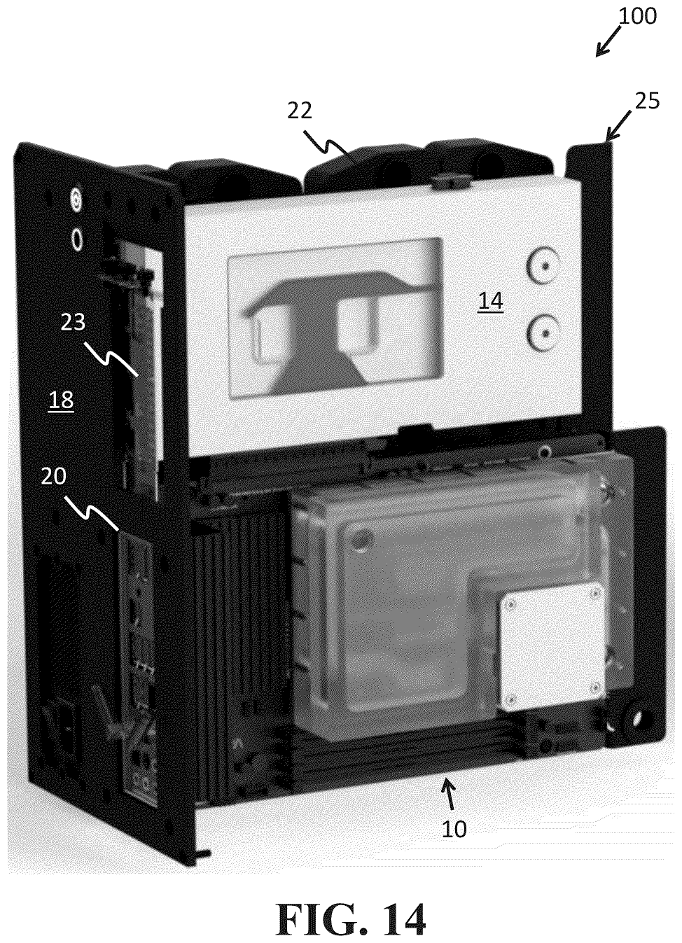

Referring now to FIG. 14, the device 100 may include a removable motherboard insert 25, according to some embodiments of the present disclosure. For instance, the removable motherboard insert 25 may include the motherboard assembly 90 depicted with reference to FIGS. 5 and 9, a mounting panel 22, and, as suggested above, the back panel 18. Of course, the mounting panel 22 may be considered an internal component of the chassis 12. Thus, the chassis 12 may include the back pabel 18, the sleeve 19, and the mounting panel 22. Such components may be secured to one another in any suitable combination. As a first example, the motherboard assembly 90 may be secured to the back panel 18 as depicted with reference to FIG. 10, and the back panel 18 may be secured to the mounting panel 22. As a second example, the motherboard assembly 90 may be secured to each of the mounting panel 22 and the back panel 18.

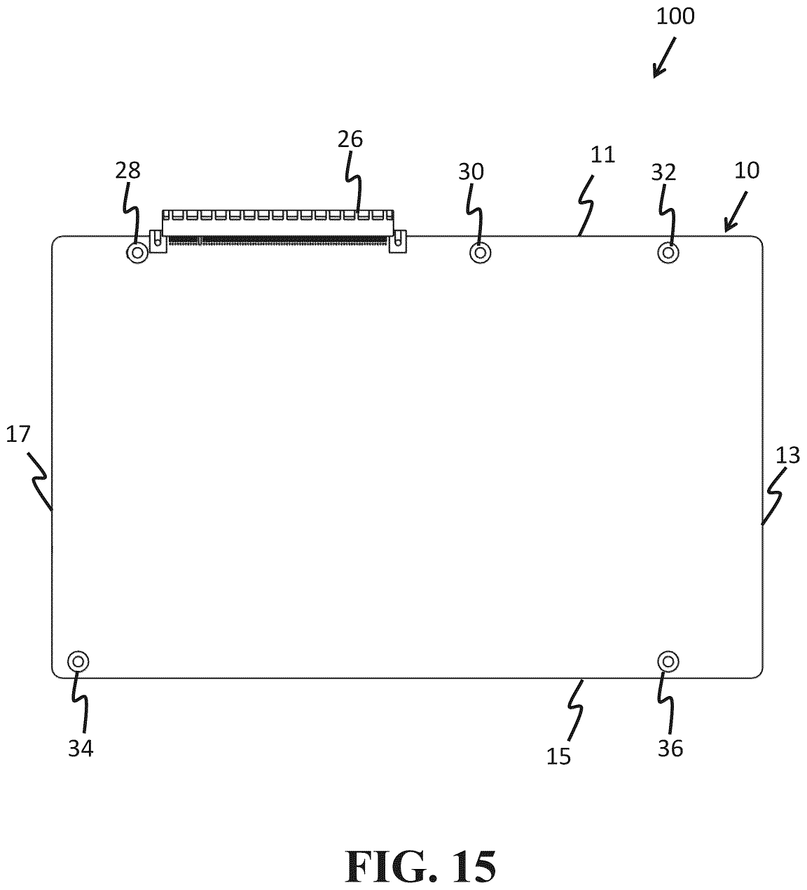

Referring now to FIG. 15, the motherboard assembly 90 may be secured to the mounting panel 22 via a number of mounting holes, according to some embodiments of the present disclosure. For instance, the motherboard 10 may include a first mounting hole 28, a second mounting hole 30, a third mounting hole 32, a fourth mounting hole 34, and a fifth mounting hole 36. As shown, the first, second, and third hole 28, 30, and 32 may be located along the first edge 11, while the fourth and fifth holes 34, 36 may be located along the third edge 15.

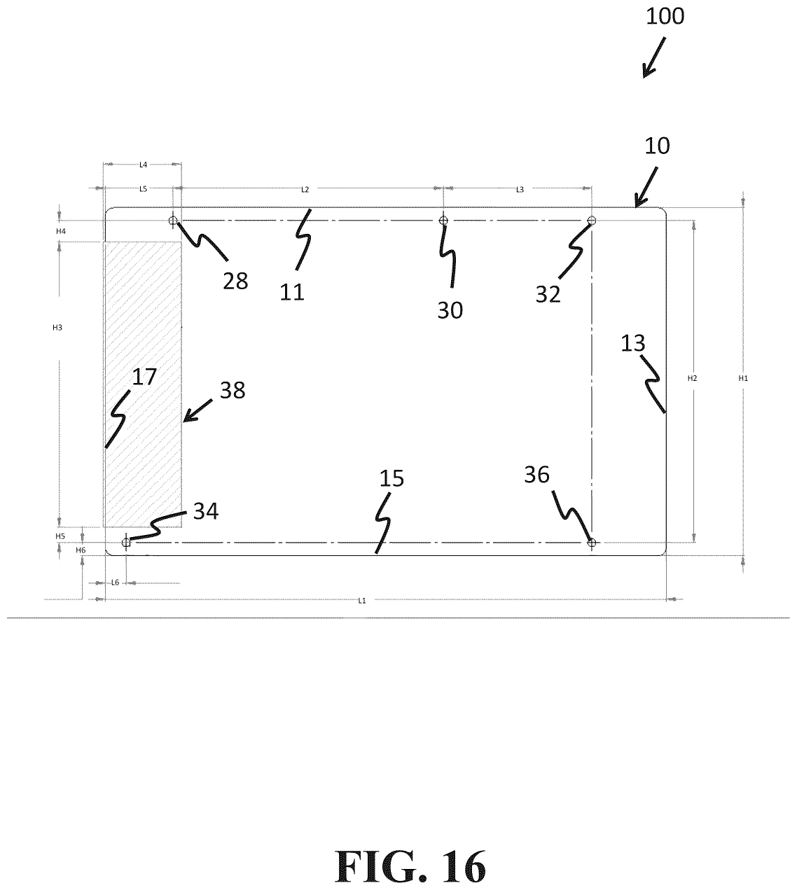

Referring now to FIG. 16, dimensions of the motherboard 10 are shown, according to some embodiments of the present disclosure. In some embodiments, a distance L1 between the first and third edges 11, 13 (e.g., the general span of the second and fourth edges 13, 17) is 9.6 inches. In some embodiments, a distance H1 between the second and fourth edges 13, 17 (e.g., the general span of the first and third edges 11, 13) is 10.78″. In other embodiments, the distance H1 is 6.7 inches.

The first, second, and third mounting holes 28, 30, 32 may be horizontally aligned (e.g., aligned on an axis parallel to the first edge 11) and vertically offset from the first edge 11 by a length H6 of 0.25 inches. The fourth and fifth mounting hole 34, 36 may be horizontally aligned and vertically offset from the third edge 15 by H6.

The first, second, and third mounting hole 28, 30, 32 may be positioned above (e.g., closer to the expansion connector 26 relative to the fourth edge 17) the fourth and fifth mounting hole 34, 36, and be vertically offset from the fourth and fifth mounting hole 34, 36 by a distance H2 of 6.2 inches.

The first mounting hole 28 may be horizontally offset from the second mounting hole 30 by a length L2 of 5.2 inches. The third mounting hole 32 may be horizontally offset from the second mounting hole 30, where the second mounting hole 30 the middle mounting hole amongst the first, second, and third mounting hole 28, 30, 32, by a length L3 of 2.85 inches.

In some embodiments, the first mounting hole 28 may be horizontally offset from the fourth edge 17 by a length L5 of 1.5 inches. In particular, the length L5 may represent a distance between the fourth edge 17 and the nearest edge of the expansion connector 26. As suggested above with reference to FIG. 10, additional IO connectors may disposed on the add-on card 14 (and secured by the IO shield 23). Such additional IO connectors may generally be vertically aligned with the forth edge 17. In this sense, such IO connectors may necessitate a horizontal gap between the fourth edge 17 and the nearest edge of the add-on card 14. Thus, the length L5 (as with any of the dimensions discussed herein) may be any dimension suitable for facilitating the apparatuses and methods discussed herein.

The fourth mounting hole 34 may be horizontally offset from the fourth edge 17 by a length L6 of 0.4 inches, and be positioned to the left of the fifth mounting hole 36. The fourth mounting hole 34 may be horizontally offset from the fifth mounting hole 36 by a length of 5.8 inches.

The IO connectors 38 may be arranged such that they are generally positioned on a rectangular region that is lower than, and vertically offset from the first, second, and third mounting hole 28, 30, 32 by a length H4 of 0.4 inches. The external connectors may be higher than, and vertically offset from the fourth and fifth mounting holes 34, 36 by a length H5 of 0.3 inches. The external connectors may be arranged such that, horizontally, the are generally aligned with the fourth edge 17 and extend onto the motherboard 10 by a length L4 of 1.5 inches.

Of course, as suggested above with reference to the length L5, the various dimensions described herein are merely exemplary in nature. It should be appreciated that the dimensions of the motherboard 10; the first, second, third, fourth, and fifth mounting holes 28, 30, 32, 34, 36; the IO connectors 38; and any other component of the device 100 discussed herein may be dimensioned or arranged in any suitable format in order to provide the advantages discussed herein.

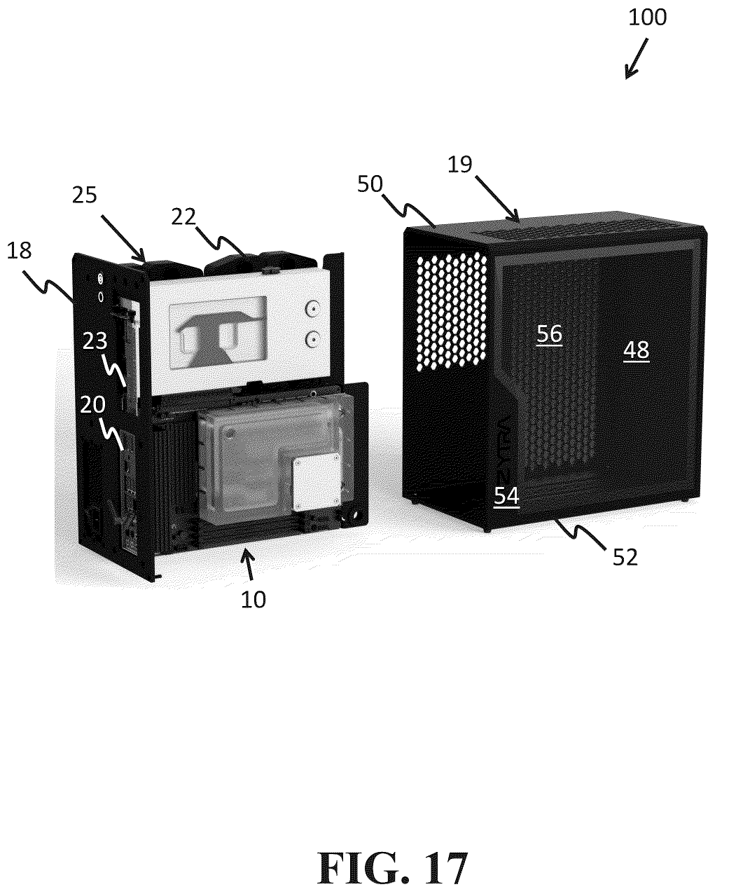

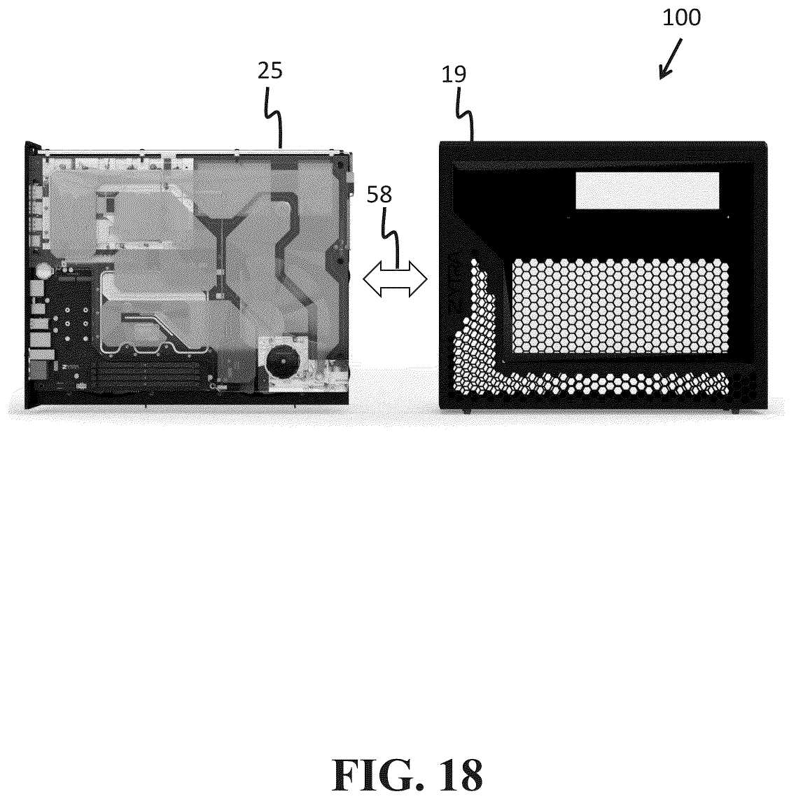

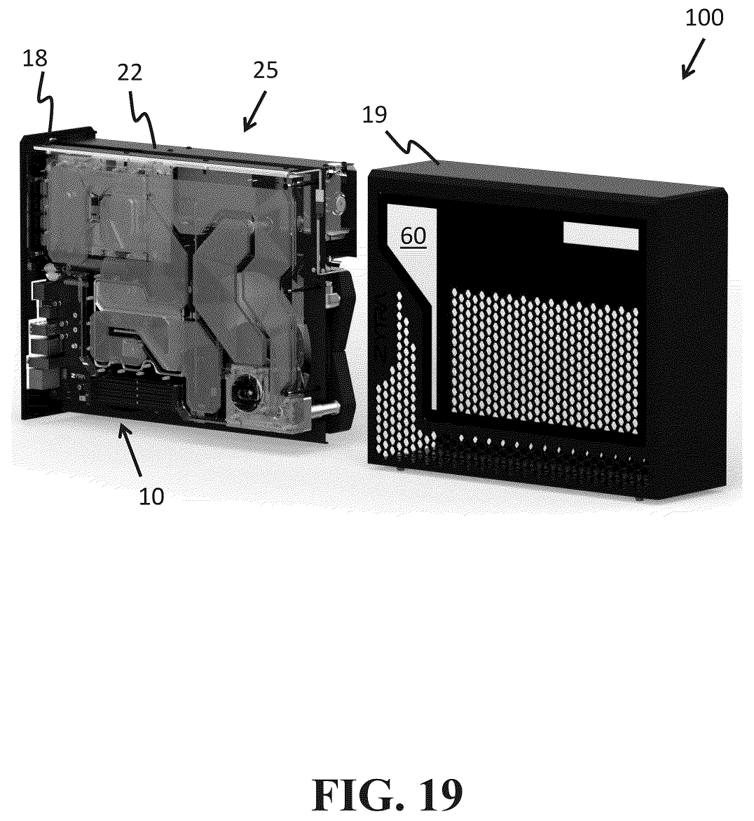

Referring now to FIGS. 17-20, the device 100 is shown to depict the removal of the removable motherboard insert 25 from, or insertion of the same into, the sleeve 19, according to some embodiments of the present disclosure. As suggested above, the sleeve 19 may be arranged such that an opening 60 is left where the back panel 18 would otherwise be. The dimensions of the removable motherboard insert 25 may be arranged such that the removable motherboard insert 25 is insertable within the sleeve 19. Generally, this advantageously provides access to the motherboard 10 in a manner that may not require significant steps or manual labor, such as disassembling a side panel, as may be the case in conventional computing devices.

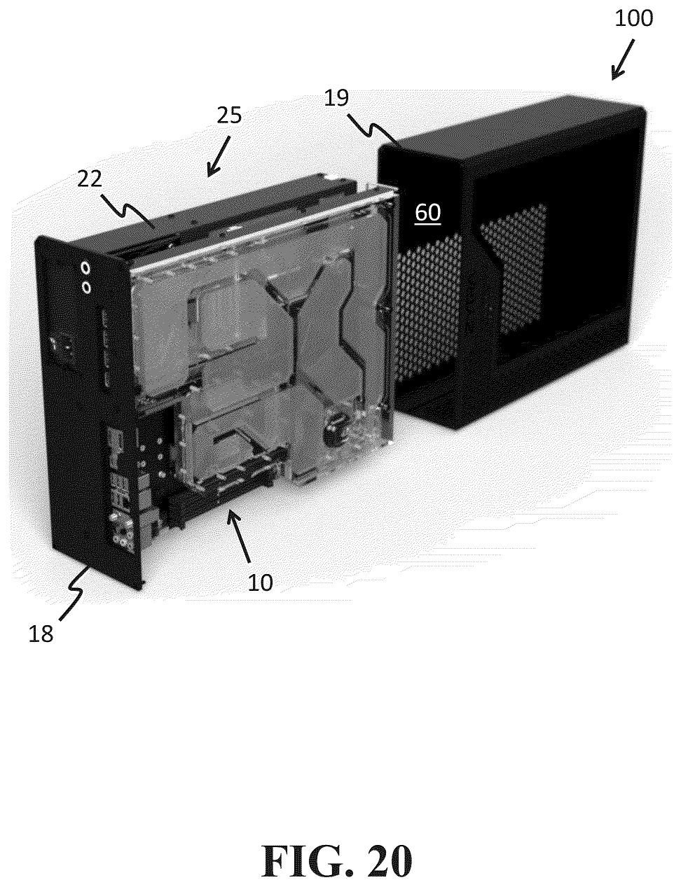

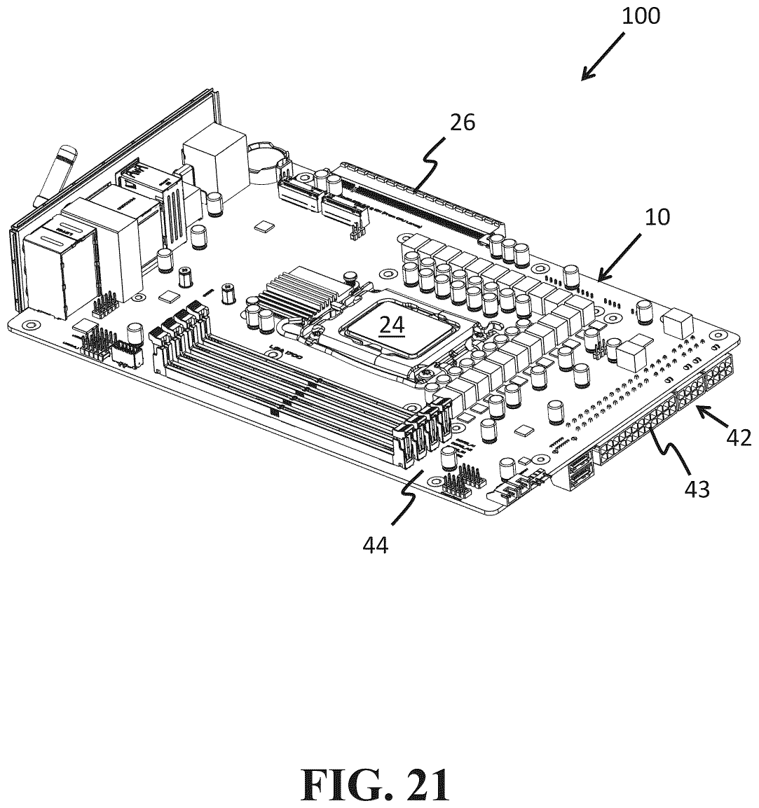

Referring now to FIGS. 20 and 21, the device 100 is shown, according to some embodiments of the present disclosure. The device 100 may include a power connector 42. The power connector 42 may be disposed on the motherboard 10 along the second edge 13, and include one or more power connector slots 43 oriented parallel relative to the motherboard 10 (similar to the discussion of the expansion connector 26 above). The power connector 42 may face in an opposite direction relative to the one or more IO connectors 38, thus facing the front panel 48 of the chassis. By orienting the power connector 42 as such, any cabling required to bridge between the power connector 42 and an external power supply may not be required to undergo as many contours that are typically required in conventional computing systems. Depending on the implementation, the power connector 42 may be disposed on the first (e.g., top) face 44 of the motherboard 10 (as shown with reference to FIG. 20), the second (e.g., bottom) face 46 of the motherboard 10, or in some other suitable configuration.

Thus, although there have been described particular embodiments of the present invention of a new and useful COMPUTER MOTHERBOARD, it is not intended that such references to particular embodiments be construed as limitations upon the scope of this invention.

What is claimed is:

1. A computing device, the device comprising:
a motherboard including a first edge, a second edge, a third edge opposite the first edge, and a fourth edge opposite the second edge, wherein the first edge is longer than the second edge;
a socket disposed on the motherboard and configured to receive a central processing unit; and
an expansion connector disposed on the motherboard along the first edge, the expansion connector including one or more expansion connector slots oriented parallel relative to the motherboard.

2. The device of claim 1, further comprising an add-on card disposed on the expansion connector, such the graphics processing unit is oriented parallel relative to the motherboard.

3. The device of claim 2, wherein the add-on card is coplanar relative to the motherboard.

4. The device of claim 3, wherein the expansion connector is a Peripheral Component Interconnect Express connector.

5. The device of claim 4, wherein the add-on card is a graphics processing unit.

6. The device of claim 5, further comprising a power connector disposed on the motherboard along the second edge, the power connector including one or more power connector slots oriented parallel relative to the motherboard.

7. The device of claim 5, further comprising one or more input/output connectors disposed on the motherboard and located along the fourth edge.

8. A computing device, the device comprising:
a chassis including a back panel, a sleeve, and a mounting panel, wherein the back panel is removably secured to the sleeve and the mounting panel is disposed on the back panel and extends into the sleeve;
a motherboard disposed on the mounting panel and oriented parallel to the mounting panel;
a socket disposed on the motherboard, the socket configured to receive a central processing unit; and
an expansion connector disposed on the motherboard, the expansion connector including one or more expansion slots oriented parallel relative to the motherboard.

9. The computing device of claim 8, wherein the expansion slots and the motherboard are oriented vertically.

10. The computing device of claim 9, further comprising an add-on card disposed on the expansion connector, the add-on card oriented vertically.

11. The computing device of claim 10, further comprising one or more input/output connectors disposed on the motherboard and facing the back panel.

12. The computing device of claim 11, wherein the back panel includes an input/output shield aligned with the add-on card.

13. The computing device of claim 8, wherein the add-on card is located above the motherboard.

14. The computing device of claim 8, wherein the add-in card is a graphics processing unit.

15. A method of providing a computing device, the method comprising:
providing a motherboard including a first edge, a second edge, a third edge opposite the first edge, and a fourth edge opposite the second edge, wherein the first edge is longer than the second edge;
installing a central processing unit on the motherboard; and
installing an add-on card on the motherboard, such that the add-on card is oriented parallel to the motherboard.

16. The method of claim 15, further comprising installing an expansion connector along the first edge of the motherboard, such that one or more expansion connector slots of the expansion connector are oriented perpendicular to the motherboard,
wherein the add-on card is disposed on the expansion connector slots.

17. The method of claim 15, further comprising:
securing the motherboard to a back panel; and
securing the back panel to a sleeve, such that the motherboard is inserted within the sleeve, and a chassis is formed by the sleeve and the back panel.

18. The method of claim 17, further comprising installing one or more input/output connectors along the fourth edge of the motherboard, such that the one or more input/output connectors face the back panel.

19. The method of claim 18, further comprising installing one a power connector along the second edge of the motherboard, such that the power connector faces in an opposite direction relative to the one or more input/output connectors.

20. The method of claim 19, wherein the add-on card is located above the motherboard.
